(19) United States
(12) Patent Application Publication
(10) Pub. No.: US 2018/0286707 A1
(43) Pub. Date: Oct. 4, 2018

(54) GAS ADDITIVES FOR SIDEWALL PASSIVATION DURING HIGH ASPECT RATIO CRYOGENIC ETCH

(71) Applicant: Lam Research Corporation, Fremont, CA (US)

(72) Inventors: Eric A. Hudson, Berkeley, CA (US); Francis Sloan Roberts, Redwood City, CA (US)

(21) Appl. No.: 15/475,021

(22) Filed: Mar. 30, 2017

(51) Int. Cl. H01L 21/67; H01L 21/311; H01L 21/683; H01J 37/32

(52) U.S. Cl. CPC H01L 21/67069; H01L 21/31116; H01L 21/31144; H01L 21/6831; H01J 2237/2001; H01J 37/32724; H01J 37/3244; H01J 37/32422; H01J 2237/3341; H01L 21/67103

(57) ABSTRACT

Methods and apparatus for etching a feature in a substrate are provided. The feature may be etched in dielectric material, which may or may not be provided in a stack of materials. The substrate may be etched using cryogenic temperatures and particular classes of reactants. In various examples, the substrate may be etched at a temperature of about −20° C. or lower, using a mixture of reactants that includes at least one reactant that is an iodine-containing fluorocarbon, an iodine-containing fluoride, a bromine-containing fluorocarbon, a sulfur-containing reactant, or one of another select set of reactants. In various embodiments, the combination of low processing temperature with particular reactants results in very effective bow control.

### BACKGROUND

One process frequently employed during fabrication of semiconductor devices is formation of an etched cylinder in dielectric material. Example contexts where such a process may occur include, but are not limited to, memory applications such as DRAM and 3D NAND structures. As the semiconductor industry advances and device dimensions become smaller, such cylinders become increasingly harder to etch in a uniform manner, especially for high aspect ratio cylinders having narrow widths and/or deep depths.

### SUMMARY

Certain embodiments herein relate to methods and apparatus for forming an etched feature in dielectric material on a semiconductor substrate. The disclosed embodiments may utilize certain techniques to deposit a passivating material on sidewalls of the etched feature, thereby allowing etch to occur at high aspect ratios.

In one aspect of the disclosed embodiments, a method of etching a feature in a substrate including dielectric material is provided, the method including: (a) receiving the substrate in a substrate holder in a chamber, the substrate holder including a chiller configured to cool the substrate; (b) cooling the substrate by cooling the chiller to a temperature of about −20° C. or lower; (c) flowing a mixture of reactants into the chamber, generating a plasma from the mixture of reactants, and etching the dielectric material of the substrate to form the feature in the substrate, where the mixture of reactants includes at least one reactant selected from the group consisting of: an iodine-containing fluorocarbon, a bromine-containing fluorocarbon, an iodine-containing fluoride, hydrogen iodide (HI), hydrogen bromide (HBr), iodine monobromide (IBr), sulfur hexafluoride (SF₆), sulfur dioxide (SO₂), carbon disulfide (CS₂), carbonyl sulfide (COS), tetrafluoromethane (CF₄), hexafluoroethane (C₂F₆), and octafluoropropane (C₃F₈), decafluorobutane (C₄F₁₀), trifluoromethane, (CHF₃), and pentafluoroethane (C₂HF₅).

In some embodiments, the mixture of reactants includes the iodine-containing fluorocarbon, and the iodine-containing fluorocarbon is selected from the group consisting of: trifluoromethyl iodide (CF₃I), iodopentafluoroethane (C₂IF₅), diiodotetrafluoroethane (C₂I₂F₄), and pentafluoroethyl iodide (C₂F₅I). In some such embodiments, the iodine-containing fluorocarbon is CF₃I. The substrate may be cooled by cooling the chiller to a temperature of about −60° C. or lower in some cases.

In one embodiment, the mixture of reactants includes at least one reactant selected from the group consisting of: iodine monobromide (IBr) and hydrogen bromide (HBr). In some such embodiments, the substrate may be cooled by cooling the chiller to a temperature of about −60° C. or lower. In some implementations, the mixture of reactants includes the bromine-containing fluorocarbon, and where the bromine-containing fluorocarbon is selected from the group consisting of: bromopentafluoroethane (C₂BrF₅), bromotrifluoromethane (CF₃Br), tribromotrifluoroethane (C₂Br₃F₃), and dibromotetrafluoroethane (C₂Br₂F₄). In a particular embodiment, the bromine-containing fluorocarbon is C₂BrF₅. In some such embodiments, the substrate is cooled by cooling the chiller to a temperature of about −40° C. or lower.

In various implementations, the mixture of reactants includes at least one reactant selected from the group consisting of: tetrafluoromethane (CF₄), hexafluoroethane (C₂F₆), and octafluoropropane (C₃F₈), decafluorobutane (C₄F₁₀), trifluoromethane, (CHF₃), and pentafluoroethane (C₂HF₅). In some embodiments, the mixture of reactants includes at least one reactant selected from the group consisting of sulfur hexafluoride (SF₆), sulfur dioxide (SO₂), carbon disulfide (CS₂), and carbonyl sulfide (COS). In some embodiments, the mixture of reactants further includes fluorocarbons and/or hydrofluorocarbons that do not include iodine, bromine, or sulfur. In these or other embodiments, the mixture of reactants may include at least one iodine-containing fluoride selected from the group consisting of: iodine monofluoride (IF), iodine trifluoride (IF₃), iodine pentafluoride (IF₅), and iodine heptafluoride (IF₇).

In certain embodiments, the substrate is etched at two or more different sets of reaction conditions, the two or more different sets of reaction conditions being different with respect to at least one variable selected from the group consisting of: chiller temperature, substrate temperature, flow rate of the mixture of reactants into the chamber, pressure in the chamber, and power used to generate the plasma. For instance, the different sets of reaction conditions may be different with respect to the chiller temperature such that the substrate is etched at two or more different temperatures. In one embodiment, the chiller reaches a temperature between about −100° C. and about −20° C. during etching.

The dielectric material of the substrate may include layers of silicon oxide, where the layers of silicon oxide alternate with layers of polysilicon. In some cases, the dielectric material of the substrate includes layers of silicon oxide and layers of silicon nitride, where the layers of silicon oxide alternate with the layers of silicon nitride. In these or other embodiments, the feature is etched to a final aspect ratio of at least about 5:1. In various implementations, a protective film forms on sidewalls of the feature during etching, where the protective film prevents or slows lateral etching of the feature as the feature is etched in a vertical direction in the substrate.

In another aspect of the disclosed embodiments, an apparatus for etching a feature in a substrate including dielectric material, the apparatus including: a reaction chamber; a substrate support including a chiller configured to cool the substrate; an inlet for introducing process gases to the reaction chamber; an outlet for removing material from the reaction chamber; a plasma source; and a controller including executable instructions for: (a) receiving the substrate in the substrate holder; (b) cooling the substrate by cooling the chiller to a temperature of about −20° C. or lower; and (c) flowing a mixture of reactants into the chamber, using the plasma source to generate a plasma from the mixture of reactants, and etching the dielectric material of the substrate to form the feature in the substrate, where the mixture of reactants includes at least one reactant selected from the group consisting of: an iodine-containing fluorocarbon, a bromine-containing fluorocarbon, an iodine-containing fluoride, hydrogen iodide (HI), hydrogen bromide (HBr), iodine monobromide (IBr), sulfur hexafluoride (SF₆), sulfur dioxide (SO₂), carbon disulfide (CS₂), carbonyl sulfide (COS), tetrafluoromethane (CF₄), hexafluoroethane (C₂F₆), and octafluoropropane (C₃F₈), decafluorobutane (C₄F₁₀), trifluoromethane, (CHF₃), pentafluoroethane (C₂HF₅).

These and other features will be described below with reference to the associated drawings.

### BRIEF DESCRIPTION OF THE DRAWINGS

FIG. 1 illustrates an etched cylinder having an undesirable bow due to over-etching of the sidewalls.

FIG. 2A is a flowchart describing a method of etching a feature according to various embodiments herein.

FIG. 2B is a flowchart describing a particular example embodiment in line with the method of FIG. 2A.

FIG. 3 depicts an etched cylinder having a protective film on the sidewalls according to certain embodiments herein.

FIGS. 4A-4C illustrate a reaction chamber that may be used to perform the etching processes described herein according to certain embodiments.

FIG. 5 shows a portion of a substrate support that may be used in certain embodiments to cool the substrate.

FIG. 6 is a graph showing a general inverse relationship between sticking coefficient and temperature, for the purpose of explanation.

### DETAILED DESCRIPTION

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the embodiments are implemented on a wafer. However, the embodiments are not so limited. The work piece may be of various shapes, sizes, and materials. In addition to semiconductor wafers, other work pieces that may take advantage of the disclosed embodiments include various articles such as printed circuit boards, magnetic recording media, magnetic recording sensors, mirrors, optical elements, micro-mechanical devices and the like.

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### I. Technology for Etching High Aspect Ratio Features in a Dielectric Material

Fabrication of certain semiconductor devices involves etching features into a dielectric material or materials. The dielectric material may be a single layer of material or a stack of materials. In some cases a stack includes alternating layers of dielectric material (e.g., silicon nitride and silicon oxide). One example etched feature is a cylinder, which may have a high aspect ratio. As the aspect ratio of such features continues to increase, it is increasingly challenging to etch the features into dielectric materials. One problem that arises during etching of high aspect ratio features is a non-uniform etching profile. In other words, the features do not etch in a straight downward direction. Instead, the sidewalls of the features are often bowed such that a middle portion of the etched feature is wider (i.e., further etched) than a top and/or bottom portion of the feature. This over-etching near the middle portion of the features can result in compromised structural and/or electronic integrity of the remaining material. The portion of the feature that bows outwards may occupy a relatively small portion of the total feature depth, or a relatively larger portion. The portion of the feature that bows outward is where the critical dimension (CD) of the feature is at its maximum. The critical dimension corresponds to the diameter of the feature at a given spot. It is generally desirable for the maximum CD of the feature to be about the same as the CD elsewhere in the feature, for example at or near the bottom of the feature.

Without being bound by any theory or mechanism of action, it is believed that the over-etching at the middle portion of the cylinder or other feature occurs at least partially because the sidewalls of the cylinder are insufficiently protected from etching. Conventional etch chemistry utilizes fluorocarbon etchants to form the cylinders in the dielectric material. The fluorocarbon etchants are excited by plasma exposure, which results in the formation of various fluorocarbon fragments including, for example, CF, CF₂, and CF₃. Reactive fluorocarbon fragments etch away the dielectric material at the bottom of a feature (e.g., cylinder) with the assistance of ions, which may be provided through direct plasma exposure or ion beams. Other fluorocarbon fragments are deposited on the sidewalls of the cylinder being etched, thereby forming a protective polymeric sidewall coating. This protective sidewall coating promotes preferential etching at the bottom of the feature as opposed to the sidewalls of the feature. Without this sidewall protection, the feature begins to assume a non-uniform profile, with a wider etch/cylinder width where the sidewall protection is inadequate.

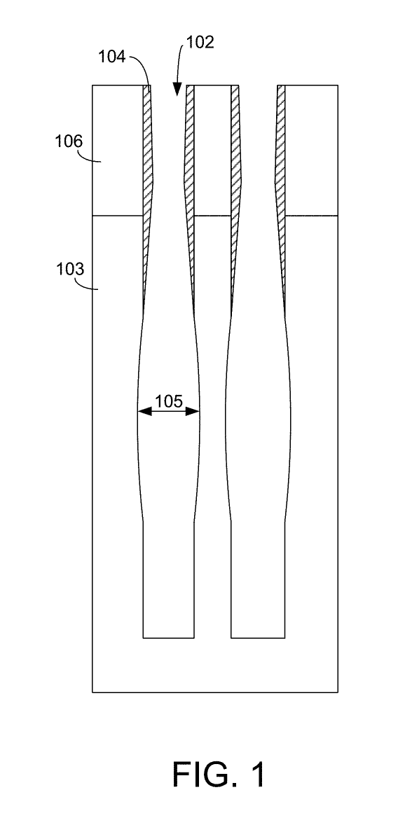

Sidewall protection is especially difficult to achieve in high aspect ratio features. One reason for this difficulty is that existing fluorocarbon-based processes cannot form the protective polymeric sidewall coating deep in the cylinder being etched. FIG. 1 presents a figure of a cylinder 102 being etched in material 103 coated with a patterned mask layer 106. Material 103 typically includes dielectric material, and may include a stack of materials as described herein. While the following discussion sometimes refers to cylinders, the concepts apply to other feature shapes such as ovals, trenches, rectangles and other polygons. A protective polymeric sidewall coating 104 is concentrated near the top portion of the cylinder 102. CₓF_{y} chemistry provides both the etch reactant(s) for etching the cylinder vertically, as well as the reactant(s) that form the protective polymeric sidewall coating 104. Because the protective polymeric sidewall coating 104 does not extend deep into the cylinder (i.e., there is insufficient deposition on the sidewall), the middle portion of the cylinder 102 becomes wider than the top portion of the cylinder 102. The wider middle portion of the cylinder 102 is referred to as the bow 105. The bow can be numerically described in terms of a comparison between the critical dimension of the feature at the bow region (the relatively wider region) and the critical dimension of the feature below the bow region. The bow may be numerically reported in terms of distance (e.g., the critical dimension at the widest part of the feature minus the critical dimension at the narrowest part of the feature below the bow) or in terms of a ratio/percent (the critical dimension at the widest part of the feature divided by the critical dimension at the narrowest part of the feature below the bow). This bow 105, and the related non-uniform etch profile, is undesirable. Because of the high ion energies often used in this type of etching process, bows are often created when etching cylinders of high aspect ratios. In some applications, bows are created even at aspect ratios as low as about 5. As such, conventional fluorocarbon etch chemistry is typically limited to forming relatively low aspect ratio cylinders in dielectric materials. Some modern applications require cylinders having higher aspect ratios than those that can be achieved with conventional etch chemistry.

### II. Context and Applications

In various embodiments herein, features are etched in a substrate (typically a semiconductor wafer) having dielectric material on the surface. The etching processes are generally plasma-based etching processes. The overall feature formation process may occur in stages: one stage directed at etching the dielectric material and another stage directed at forming a protective sidewall coating without substantially etching the dielectric material. The protective sidewall coating passivates the sidewalls and prevents the feature from being over-etched (i.e., the sidewall coating prevents lateral etch of the feature). These two stages can be repeated until the feature is etched to its final depth. By cycling these two stages, the diameter of the feature can be controlled over the entire depth of the feature, thereby forming features having more uniform diameters/improved profiles.

A feature is a recess in the surface of a substrate. Features can have many different shapes including, but not limited to, cylinders, ovals, rectangles, squares, other polygonal recesses, trenches, etc.

Aspect ratios are a comparison of the depth of a feature to the critical dimension of the feature (often its width/diameter). For example, a cylinder having a depth of 2 μm and a width of 50 nm has an aspect ratio of 40:1, often stated more simply as 40. Since the feature may have a non-uniform critical dimension over the depth of the feature, the aspect ratio can vary depending on where it is measured. For instance, sometimes an etched cylinder may have a middle portion that is wider than the top and bottom portions. This wider middle section may be referred to as the bow, as noted above. An aspect ratio measured based on the critical dimension at the top of the cylinder (i.e., the neck) would be higher than an aspect ratio measured based on the critical dimension at the wider middle/bow of the cylinder. As used herein, aspect ratios are measured based on the critical dimension proximate the opening of the feature, unless otherwise stated.

The features formed through the disclosed methods may be high aspect ratio features. In some applications, a high aspect ratio feature is one having an aspect ratio of at least about 5, at least about 10, at least about 20, at least about 30, at least about 40, at least about 50, at least about 60, at least about 80, or at least about 100. The critical dimension of the features formed through the disclosed methods may be about 200 nm or less, for example about 100 nm or less, about 50 nm or less, or about 20 nm or less.

The material into which the feature is etched may be a dielectric material in various cases. Example materials include, but are not limited to, silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular example materials include stoichiometric and non-stoichiometric formulations of SiO₂, SiN, SiON, SiOC, SiCN, etc. The material or materials being etched may also include other elements, for example hydrogen in various cases. In some embodiments, a nitride and/or oxide material being etched has a composition that includes hydrogen. As used herein, it is understood that silicon oxide materials, silicon nitride materials, etc. include both stoichiometric and non-stoichiometric versions of such materials, and that such materials may have other elements included, as described above.

One application for the disclosed methods is in the context of forming a DRAM device. In this case, the feature may be etched primarily in silicon oxide. The substrate may also include one, two, or more layers of silicon nitride, for instance. In one example, a substrate includes a silicon oxide layer sandwiched between two silicon nitride layers, with the silicon oxide layer being between about 800-1200 nm thick and one or more of the silicon nitride layers being between about 300-400 nm thick. The etched feature may be a cylinder having a final depth between about 1-3 μm, for example between about 1.5-2 μm. The cylinder may have a width between about 20-50 nm, for example between about 25-30 nm. After the cylinder is etched, a capacitor memory cell can be formed therein.

Another application for the disclosed methods is in the context of forming a vertical NAND (VNAND, also referred to as 3D NAND) device. In this case, the material into which the feature is etched may have a repeating layered structure. For instance, the material may include alternating layers of oxide (e.g., SiO₂) and nitride (e.g., SiN), or alternating layers of oxide (e.g., SiO₂) and polysilicon. The alternating layers form pairs of materials. In some cases, the number of pairs may be at least about 20, at least about 30, at least about 40, at least about 60, or at least about 70. The oxide layers may have a thickness between about 20-50 nm, for example between about 30-40 nm. The nitride or polysilicon layers may have a thickness between about 20-50 nm, for example between about 30-40 nm. The feature etched into the alternating layer may have a depth between about 2-8 μm, for example between about 3-5 μm. The feature may have a width between about 50-150 nm, for example between about 50-100 nm.

### III. Etching Process

In various embodiments, the etching process is a reactive ion etch process that involves flowing a chemical etchant into a reaction chamber (often through a showerhead), generating a plasma from, inter alia, the etchant, and exposing a substrate to the plasma. The plasma dissociates the etchant compound(s) into neutral species and ion species (e.g., charged or neutral materials such as CF, CF₂ and CF₃). The plasma is a capacitively coupled plasma in many cases, though other types of plasma may be used as appropriate. Ions in the plasma are directed toward the wafer and cause the dielectric material to be etched away upon impact.

Example apparatus that may be used to perform the etching process include the 2300® FLEX™ product family of reactive ion etch reactors available from Lam Research Corporation of Fremont, Calif. This type of etch reactor is further described in the following U.S. Patents, each of which is herein incorporated by reference in its entirety: U.S. Pat. No. 8,552,334, and U.S. Pat. No. 6,841,943.

The methods disclosed herein are particularly useful for etching semiconductor substrates having dielectric materials thereon. Example dielectric materials include silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular example materials include stoichiometric and non-stoichiometric formulations of SiO₂, SiN, SiON, SiOC, SiCN, etc. As noted above, the dielectric material that is etched may include more than one type/layer of material. In particular cases, the dielectric material may be provided in alternating layers of SiN and SiO₂ or alternating layers of polysilicon and SiO₂. The substrate may have an overlying mask layer that defines where the features are to be etched. In certain cases, the mask layer is Si, and it may have a thickness between about 500-1500 nm. In certain other cases, the mask layer may be carbon-based.

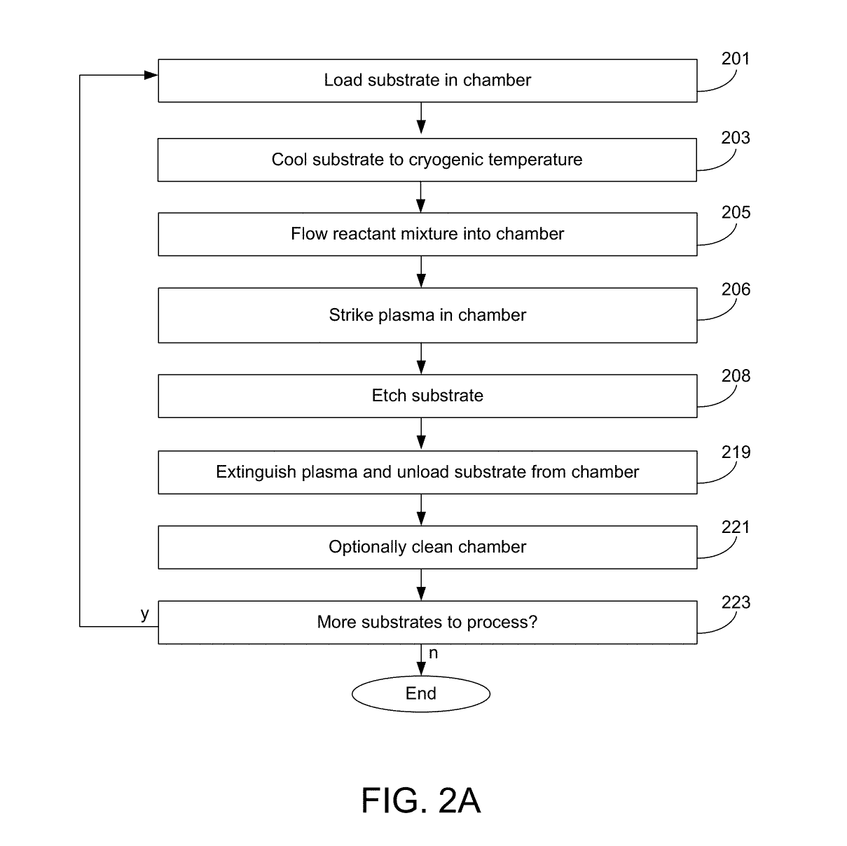

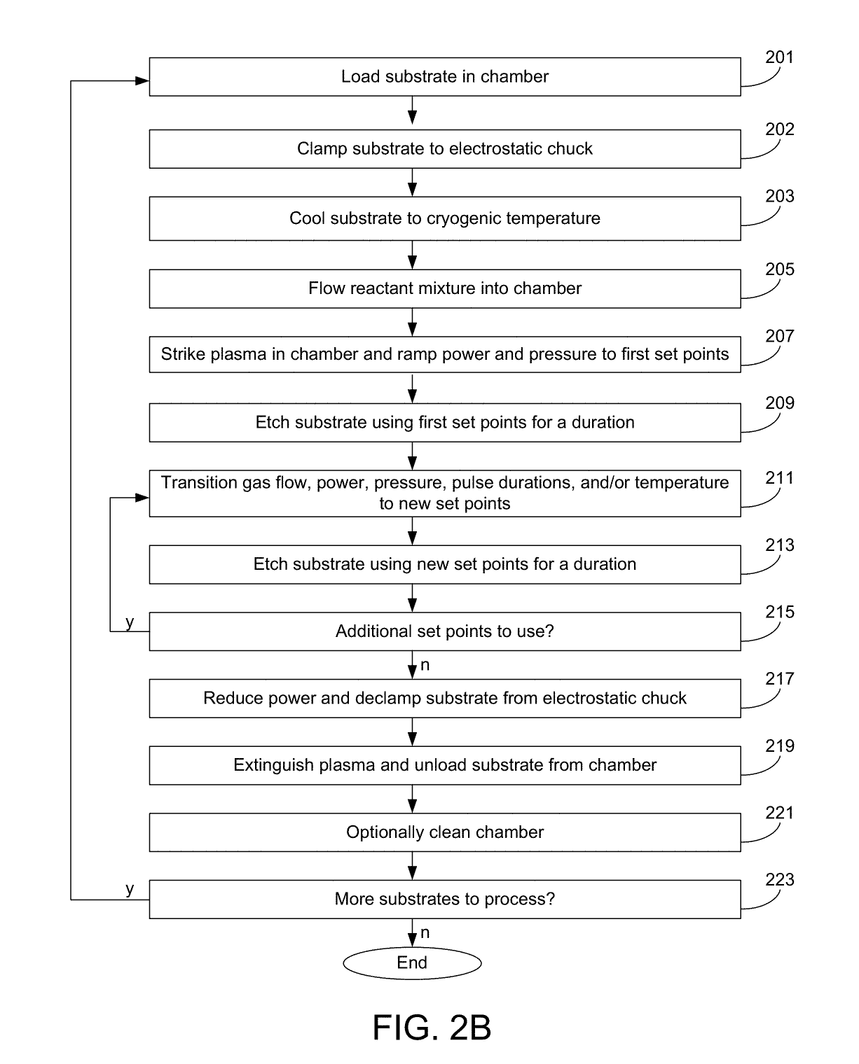

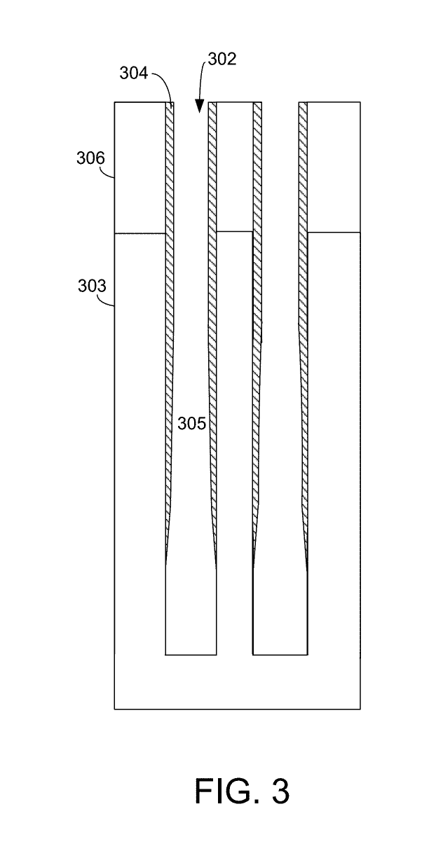

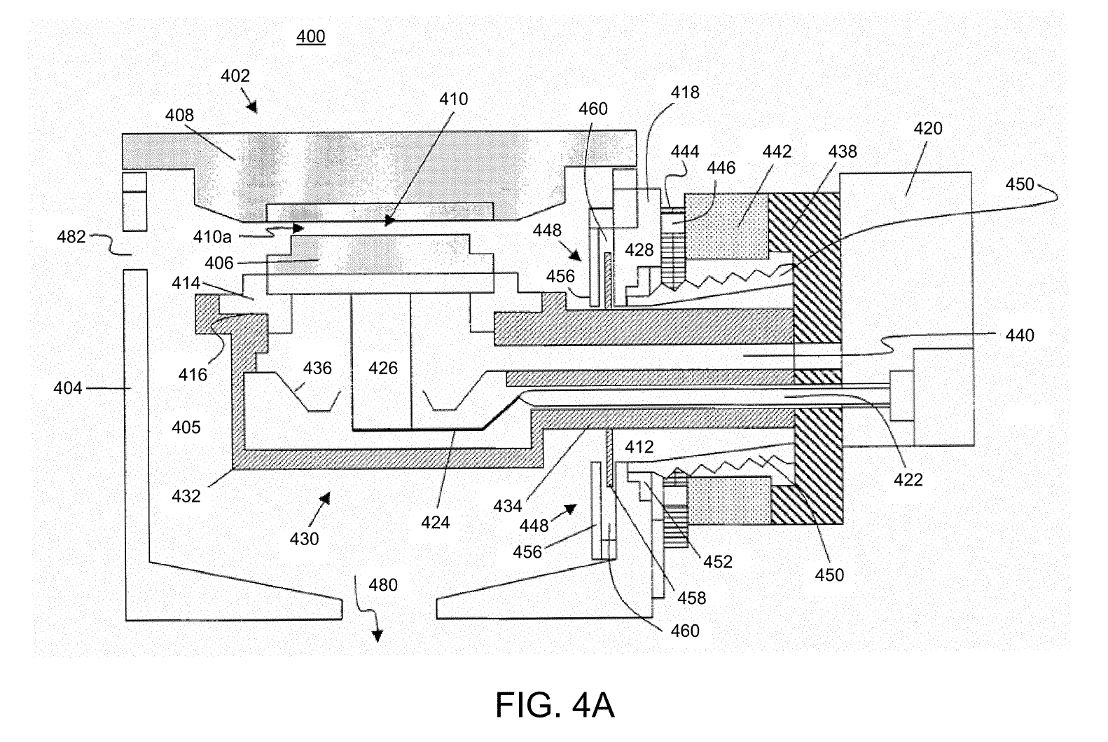

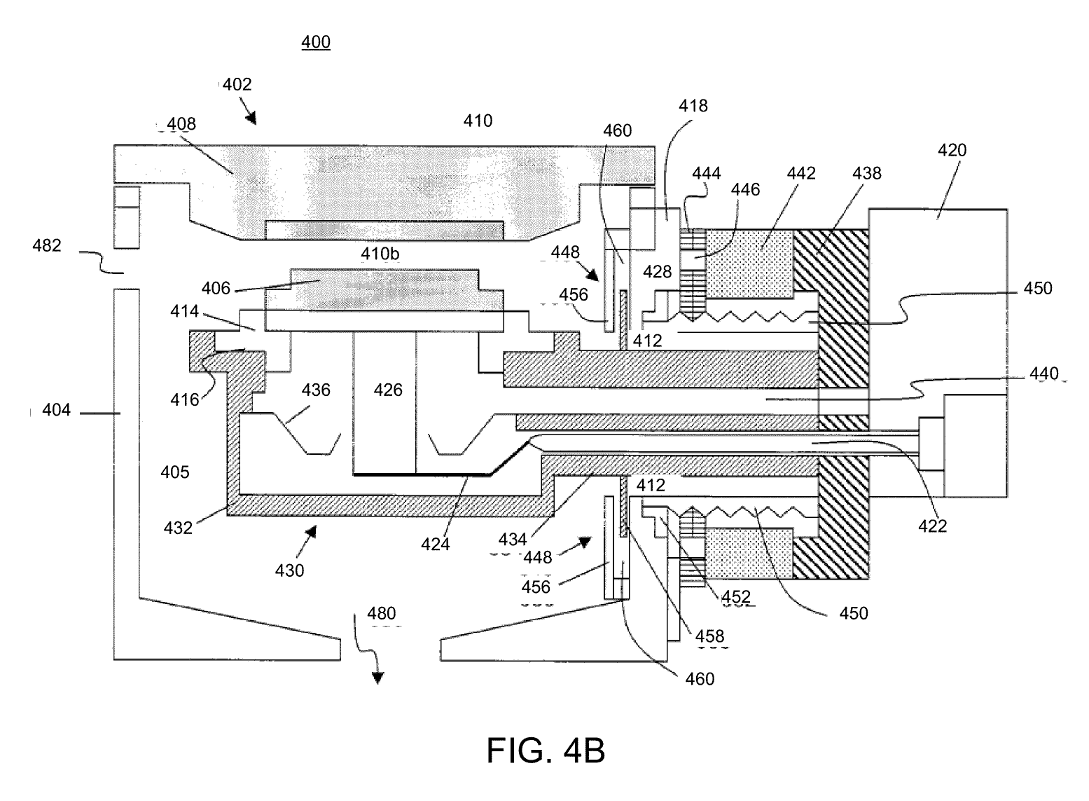

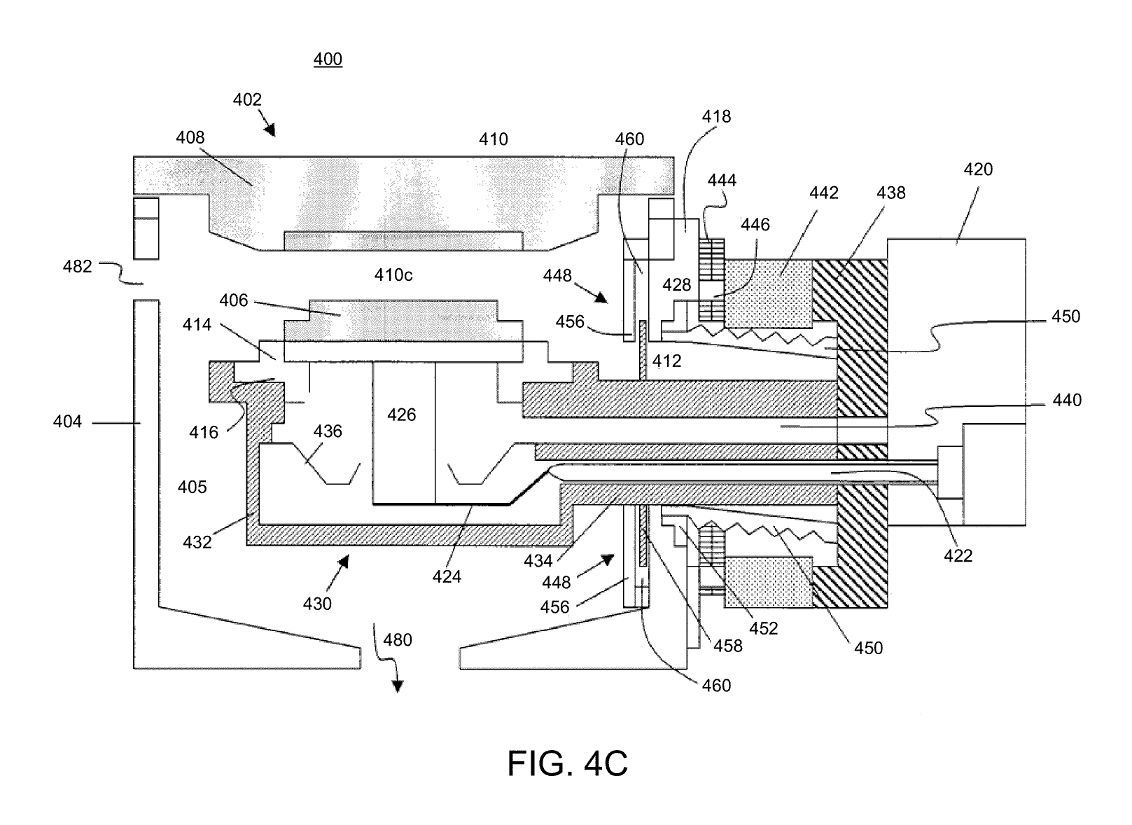

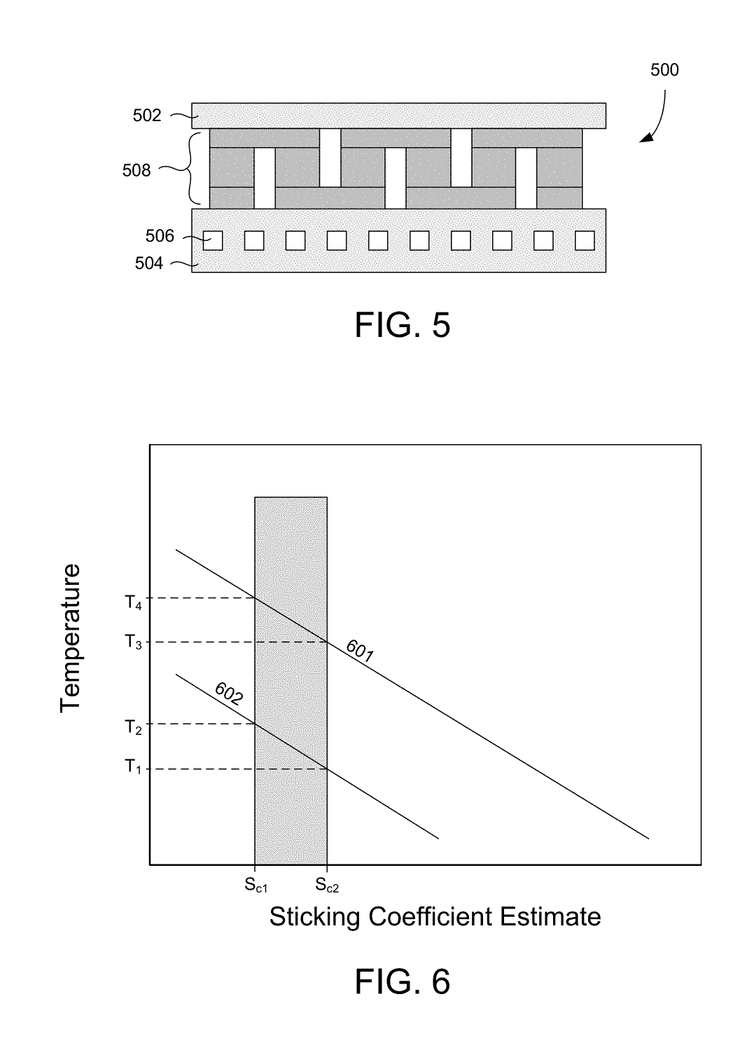

FIG. 2A presents a flowchart for a method of forming an etched feature in a semiconductor substrate. FIG. 2B presents a flowchart describing a particular example embodiment in line with the method of FIG. 2A. The methods of FIGS. 2A and 2B use particular reactants at cryogenic substrate temperatures to achieve high quality etching results. The operations shown in FIGS. 2A and 2B are described in relation to FIG. 3, which shows a partially fabricated semiconductor substrate during or after an etching process to form a recessed feature therein. The operations are also described in relation to FIGS. 4A-4C, which show an etching apparatus, and to FIG. 5, which shows a portion of a substrate support, and to FIG. 6, which shows a graph depicting the general relationship between sticking coefficient and temperature.

With reference to FIG. 2A, the method begins with operation 201, where a substrate is loaded into a reaction chamber. One example reaction chamber is described below with reference to FIGS. 4A-4C. The substrate may be loaded into a substrate support such as an electrostatic chuck in some cases. At operation 203, the substrate is cooled to a cryogenic temperature. As used herein, cryogenic temperature refers to a temperature that is about −20° C. or lower. In some cases, a cryogenic temperature may be within a certain range, for example between about −100° C. and −20° C., or between about −80° C. and −20° C., or between about −80° C. and −30° C. In certain implementations, the substrate may be cooled to a temperature of about −20° C. or below, or about −30° C. or below, or about −40° C. or below, or about −50° C. or below. In these or other cases, the substrate may be cooled to a temperature that is about −80° C. or higher, or about −70° C. or higher, or about −60° C. or higher, or about −50° C. or higher. The ideal range will depend on a variety of factors including, but not limited to, the chemistry being used, the geometry of the features being etched, the material being etched, etc. As mentioned elsewhere herein, the temperature of the substrate may be controlled via a chiller. The temperature of the chiller may be lower than the temperature of the substrate itself. In various examples, the chiller temperature may be as low as about −100° C., and the temperature of the substrate itself may be as low as about −80° C.

The temperature of the substrate is difficult to measure, for example due to plasma effects that heat up the substrate surface during processing. As used herein, the temperature of the substrate is intended to refer to the temperature of the substrate holder, unless otherwise noted. This temperature may also be referred to as the chiller temperature. The substrate holder can control the temperature of the substrate using various heating and cooling mechanisms.

In one example, the cooling mechanism may involve flowing cooling fluids through piping in or adjacent the substrate support. In another example, the cooling mechanism may involve circulation within the substrate support of single or mixed refrigerants at cryogenic temperatures. In another example, the cooling mechanism may involve a plurality of Peltier devices that may be incorporated into or next to the substrate support. One example substrate support having a plurality of Peltier devices therein for cooling and/or heating the substrate is further discussed in relation to FIG. 5, below. In another example, the substrate support may include one or more cryostats therein or thereon to achieve cooling. Temperature controlled substrate supports are further described in U.S. patent application Ser. No. 13/908,676, filed Jun. 3, 2013, and titled “TEMPERATURE CONTROLLED SUBSTRATE SUPPORT ASSEMBLY,” which is herein incorporated by reference in its entirety. Methods of etching at cryogenic temperatures are further discussed in U.S. patent application Ser. No. 15/054,023, filed Feb. 25, 2016, and titled “ION BEAM ETCHING UTILIZING CRYOGENIC WAFER TEMPERATURES,” which is herein incorporated by reference in its entirety. In various embodiments, two or more cooling mechanisms may be provided. The use of multiple cooling mechanisms may allow the substrate temperature to be changed substantially faster.

Without wishing to be bound by theory or mechanism of action, it is believed that cryogenic etching temperatures can be used to tune the sticking coefficients for the various reactants and other species present during etching. Sticking coefficient is a term used to describe the ratio of the number of adsorbate species (e.g., atoms or molecules) that adsorb/stick to a surface compared to the total number of species that impinge upon that surface during the same period of time. The symbol S_{c} is sometimes used to refer to the sticking coefficient. The value of S_{c} is between 0 (meaning that none of the species stick) and 1 (meaning that all of the impinging species stick). Various factors affect the sticking coefficient including the type of impinging species, surface temperature, surface coverage, structural details of the surface, composition of the surface, and the kinetic energy of the impinging species. Certain species are inherently more “sticky” than others, making them more likely to adsorb onto a surface each time the specie impinges on the surface. These more sticky species have greater sticking coefficients (all other factors being equal), and are more likely to adsorb near the entrance of a recessed feature compared to less sticky species having lower sticking coefficients. With reference to FIG. 1, the fluorocarbon species such as those employed in conventional etch processes using conventional etch temperatures (which may form polymeric sidewall coatings) have relatively high sticking coefficients, and therefore become concentrated near the top of the feature 102 where they first impinge upon the sidewalls. By comparison, species having lower sticking coefficients, even if they impinge upon the surface near the top of the sidewalls, are less likely to adsorb during each impact, and therefore have a greater probability of reaching the bottom portion of the feature.

On the other hand, if the sticking coefficients are too low, there may be insufficient deposition of protective material (analogous to polymeric sidewall coating 104 of FIG. 1) at the bow location, particularly as compared to other regions of the feature (e.g., regions below the bow region). In many implementations, it is desirable to form a protective film such that it is relatively thicker in regions were a bow would otherwise form, and relatively thinner (and/or non-existent) in regions below this. This protective film acts as a sacrificial layer and ensures that during etching the critical dimension of the bow region does not grow substantially compared to the critical dimension below the bow region, resulting in a more vertical etch profile. This result is possible when the sticking coefficients of the relevant species are not too low.

Moreover, the thermal diffusion of the various species in the plasma is different at cryogenic etch temperatures compared to conventional etch temperatures. The temperature affects the behavior of each species present, and the effects may not be uniform for the different species. For instance, it is believed that thermal diffusion drives larger molecules toward colder surfaces. As such, by tuning the etch temperature, the relative balance of species reaching the substrate/feature can be tuned.

FIG. 6 generally illustrates the relationship between sticking coefficient and temperature. This graph is intended to convey an inverse relationship between sticking coefficient and temperature for the purpose of explanation. However, it should be understood that the relationship shown is not necessarily accurate outside of the general inverse relationship. For instance, while lines 601 and 602 are straight/linear, in practice the relationship may be more complicated. Typically, higher substrate temperatures lead to lower sticking coefficients, and vice versa. They gray region between S_{c1} and S_{c2} represents an ideal range for the sticking coefficient for the purpose of targeting the deposition at the bow region. This ideal range is determined based on the considerations described above. In many conventional applications, the trend has been to use relatively high substrate temperatures (e.g., between 40°-80° C.) to lower the sticking coefficients of the relevant species such that the protective film forms deeper into the feature. Conventional dielectric etch at high aspect ratio is often performed at greater than 0° C.

The conventional reactants may follow line 601, with an ideal temperature range between the relatively high temperatures T₃ and T₄. However, it has been found that certain species exhibit different behavior, for example following line 602. For these species, the ideal temperature range (which achieves the ideal range of sticking coefficients) is much lower, between T₁ and T₂. This behavior was unexpected considering the behavior of previously used reactants, which often needed to be heated to achieve the desired regime.

By using a low substrate temperature in combination with certain reactants, a high quality protective film can be formed on sidewalls of the partially etched features during etching. Notably, the protective film can be formed sufficiently deep within the feature to minimize or prevent bowing of the feature as it is etched. Similarly, the protective film can be formed with sufficient thickness in the bow region (particularly compared to regions below the bow region), such that the bow does not grow relative to the rest of the feature during etching.

For instance, as shown in FIG. 3, the protective film 304 forms relatively deep into the feature 302, past region 305 where the bow would otherwise form if the protective film 304 were not present. The protective film 304 does not extend all the way to the bottom of the feature, ensuring that the bottom of the feature can be properly etched open to achieve a desired critical dimension. In some other cases the protective film 304 may extend all the way down the sidewalls. The feature 302 is etched in material 303, which typically includes one or more dielectric material. As described in relation to material 103 of FIG. 1, the material 303 may include a stack of materials. Overlying material 303 is a patterned mask layer 306. As compared to the polymeric sidewall coating 104 of FIG. 1, the protective film 304 extends deeper into the feature and is less likely to clog the opening of the feature. Further, the polymeric sidewall coating 104 is often a combination of polymer (e.g., fluorocarbon and/or hydrofluorocarbon) and redeposited etch products (e.g., SiFₓ, SiBrₓ, SiBrOₓ, SiClₓ, SiClOₓ, etc.). By comparison, the protective film 304 may be similar in composition to the protective film 104, or may be quite different, depending on the choice of reactant mixture and other conditions.

Returning to FIG. 2A, the method continues with operation 205, where a reactant mixture is flowed into the chamber. The reactant mixture may include a variety of reactants that may each serve one or more purposes. The reactant mixture includes etch chemistry, which is often fluorocarbon- and/or hydrofluorocarbon-based. As discussed in relation to FIG. 6 above, one or more particular reactants may be included, where the particular reactants are selected such that they exhibit a sticking coefficient within a desired range at cryogenic temperatures. Such reactants may include molecules having relatively large and/or heavy atoms (e.g., iodine, bromine, etc.). Often such reactants may include more than one species of halogen (e.g., iodine and fluorine, or bromine and fluorine). Such reactants may also include molecules (e.g., perfluorocarbons) which are not considered to be effective for sidewall passivation at conventional non-cryogenic processing temperatures.

Examples of such reactants include, but are not limited to, fluorocarbons and hydrofluorocarbons (e.g. trifluoromethane (CHF₃), tetrafluoromethane (CF₄), hexafluoroethane (C₂F₆), octafluoropropane (C₃F₈), etc), iodine-containing fluorocarbons (e.g., trifluoromethyl iodide (CF₃I), iodopentafluoroethane (C₂IF₅), diiodotetrafluoroethane (C₂I₂F₄), pentafluoroethyl iodide (C₂F₅I), etc.), iodine-containing fluorides (e.g., iodine monofluoride (IF), iodine trifluoride (IF₃), iodine pentafluoride (IF₅), iodine heptafluoride (IF₇), etc.), hydrogen iodide (HI), bromine-containing fluorocarbons (e.g., tribromotrifluoroethane (C₂Br₃F₃), dibromotetrafluoroethane (C₂Br₂F₄), bromopentafluoroethane (C₂BrF₅), bromotrifluoromethane (CF₃Br), etc.), other bromine-containing reactants (e.g., iodine monobromide (IBr), hydrogen bromide (HBr), etc.), and sulfur-containing reactants (e.g. sulfur hexafluoride (SF₆), hydrogen sulfide (H₂S), sulfur dioxide (SO₂), carbon disulfide (CS₂) carbonyl sulfide (COS), and other sulfur-containing reactants). In some instances, the benefits of sulfur-containing reactants may be realized in combination with polymerizing reactants, through the vulcanizing effect of sulfur to cross-link polymers. It should be noted that CF₃Br is tightly regulated in the United States due to ozone-depleting properties. These reactants may be combined with one another in any combination, including with various etchants and/or co-reactants as described below.

In various cases, the etching chemistry may include other etchants such as nitrogen trifluoride (NF₃), difluoromethane (CH₂F₂), fluoromethane (CH₃F), octafluorocyclobutane (C_{I}F₈), 1,3 hexafluorobutadiene (C₄F₆), pentafluoroethane (C₂HF₅), tetrafluoroethane (C₂H₂F₄, both isomers: 1,1,1,2-tetrafluoroethane, and 1,1,2,2-tetrafluoroethane). One or more co-reactants may also be provided. In some cases methane (CH₄), nitrogen (N₂), oxygen (O₂) and/or hydrogen (H₂) may be provided as a co-reactant. The hydrogen, nitrogen, or oxygen may help moderate formation of a protective polymer sidewall coating or other protective film on the sidewalls, for example in the upper part of the feature where sidewall deposition may be excessive. Rare gases (helium, neon, argon, krypton, xenon) may also be added as diluents. Any combination of the listed gases may be used in various embodiments.

In certain implementations, the etching chemistry includes a combination of fluorocarbons (e.g., any of the iodine-containing fluorocarbons, bromine-containing fluorocarbons, sulfur-containing fluorocarbons, perfluorocarbons, hydrofluorocarbons, etc. described herein) and oxygen. For instance, in one example the etching chemistry includes Ar, O₂, CF₄, and C₂IF₅. In another example the etching chemistry includes CF₃Br, CF₄, Ar, and O₂. In another example the etching chemistry includes HBr, H₂, NF₃, and CH₃F. In another example, the etching chemistry includes HI, CF₄, O₂, and Ar. In another example the etching chemistry includes CF₃I, CH₂F₂, NF₃, and H₂. In yet another example, the etching chemistry includes CF₃I, SF₆, and C₂HF₅. Other conventional etching chemistries may also be used, as may non-conventional chemistries. The fluorocarbons/hydrofluorocarbons may flow at a rate between about 0-500 sccm, for example between about 10-200 sccm. The flow of oxygen, nitrogen, or hydrogen may range between about 0-500 sccm, for example between about 10-200 sccm. The flow of iodine-containing gases and/or bromine-containing gases may range between about 0-200 sccm, for example between about 150 sccm. These rates are appropriate in a reactor volume of approximately 50 liters, and can be scaled accordingly. In some embodiments, the pressure during etching is between about 5-100 mTorr.

Some of the reactants described herein as being particularly useful at cryogenic temperatures have also been used at non-cryogenic temperatures for other reasons. One such example reactant is CHF₃, which has been used in some cases at non-cryogenic temperatures to improve selectivity to etch masks in the etching of silicon dioxide. However, such reactants can perform very different functions (e.g., sidewall protection to prevent over-etching and minimize bowing at large aspect ratios) when used at the cryogenic temperatures described herein.At operation 206, a plasma is struck in the chamber. The maximum ion energy at the substrate may be relatively high, for example between about 1-10 kV. The maximum ion energy is determined by the applied RF power in combination with the details of electrode sizes, electrode placement, and chamber geometry. In various cases, dual-frequency RF power is used to generate the plasma. Thus, the RF power may include a first frequency component (e.g., about 400 kHz) and a second frequency component (e.g., about 60 MHz). Different powers may be provided at each frequency component. For instance, the first frequency component (e.g., about 400 kHz) may be provided at a power between about 3-10 kW, for example about 5 kW, and the second frequency component (e.g., about 60 MHz) may be provided at a different power, for example between about 0.5-5 kW, for example about 4 kW. These power levels assume that the RF power is delivered to a single 300 mm wafer. The power levels can be scaled linearly based on substrate area for additional substrates and/or substrates of other sizes (thereby maintaining a uniform power density delivered to the substrate). In other cases, three-frequency RF power may be used to generate the plasma. In other cases, the applied RF power may be pulsed at repetition rates of 1-50000 Hz. The RF power may be pulsed between two non-zero values (e.g., between higher power and lower power states) or between zero and a non-zero value (e.g., between off and on states). Where the RF power is pulsed between two non-zero values, the powers mentioned above may relate to the higher power state, and the lower power state may correspond to an RF power of about 600 W or lower.

At operation 208, the substrate is etched. The substrate may be etched via ions and/or radicals in the plasma. In some cases, the substrate may be directly exposed to the plasma. In other cases, the substrate may be shielded from the plasma by one or more grids, where the grids include apertures that are used to form ion beams to which the substrate is exposed. In some cases, there may be two or more steps to etching the substrate, for example with different reaction conditions (e.g., different substrate temperature, pressure, flow rate of reactants, RF power, and/or RF duty cycle, etc.). An example is further explained in relation to FIG. 2B.

At operation 219, the plasma is extinguished and the substrate is unloaded from the chamber. At operation 221, the chamber may be optionally cleaned. The cleaning may occur while there is no substrate present. The cleaning may involve, e.g., exposing chamber surfaces to cleaning chemistry, which may be provided in the form of plasma. At operation 223, it is determined whether there are additional substrates to process. If so, the method repeats from operation 201 on a new substrate. Otherwise, the method is complete.

The total etch depth will depend on the particular application. For some cases (e.g., DRAM) the total etch depth may be between about 1.5-2 μm. For other cases (e.g., VNAND) the total etch depth may be at least about 3 μm, for example at least about 4 μm. In these or other cases, the total etch depth may be about 10 μm or less.

The operations shown in FIGS. 2A and 2B do not necessarily occur in the order shown. Some operations may overlap in time, and some operations may occur at earlier or later times compared to what is shown in the figures. Notably, operation 203 (which involves cooling the substrate to a cryogenic temperature) may occur at any point in time while the substrate is in the chamber. In some cases, substantially the entire etching process may be done with the substrate at cryogenic temperatures. In some other cases, one or more steps (e.g., one or more stages in operation 208 and/or other operations) may be performed at relatively higher temperatures, e.g., at least about −20° C., or at least about 0° C., or at least about 20° C.

FIG. 2B describes a particular embodiment in line with the method described in FIG. 2A. Generally, where the same reference numeral is used, the same operation is described, and any details provided above similarly apply here. The method begins at operation 201, where a substrate is loaded into the chamber. At operation 202, the substrate is clamped to an electrostatic chuck. At operation 203, the substrate is cooled to a cryogenic temperature as described above. The substrate may be cooled to a first set point temperature. In a particular example, this cooling may be done by flowing helium over the back side of the substrate, and/or over a heat exchanger thermally coupled to the substrate. At operation 205, a reactant mixture is flowed into the chamber. The pressure inside the chamber may be stabilized during this operation. At operation 207, a plasma is struck in the chamber and the RF power used to generate the plasma is ramped up. The pressure may be similarly ramped up or down during this operation. The RF power and pressure (as well as the substrate temperature) may be configured to reach a first set point.

At operation 209, the substrate is etched using the first set points for a duration. After some time, the variables including gas flow, powers, pulsing durations, pressure, and/or temperature may be transitioned to a new set point at operation 211. Any one or more of these variables may change between the first set point conditions and the second (or n^{th}) set point conditions. At operation 213, the substrate is further etched using the new set point conditions for an additional duration. At operation 215, it is determined whether there are any additional set points to use. This determination may be made based on the recipe that is followed for etching the substrate. In a particular example, three sets of set point conditions are used such that the substrate is etched under three different regimes. The plasma may or may not be extinguished between the different set points. In various cases, the etch is continuous and the set points are changed without extinguishing the plasma. If there are additional set points to use, the method repeats beginning at operation 211.

Once there are no further set points to use, the method continues with operation 217 where the power is reduced and the substrate is declamped from the electrostatic chuck. At operation 219, the plasma is extinguished and the substrate is unloaded from the chamber. At operation 221, the chamber is optionally cleaned. At operation 223, it is determined whether there are additional substrates to process. If so, the method repeats starting with operation 201 where a new substrate is loaded into the chamber for processing. Otherwise, the method is complete.

In a particular embodiment of the method described in FIG. 2A or FIG. 2B, operation 203 involves cooling the substrate to a temperature between about −70° C. and −50° C. (e.g., about −60° C.), and operation 205 involves flowing a reactant mixture into the chamber, where the reactant mixture includes CF₃I. In another embodiment, operation 203 involves cooling the substrate to a temperature between about −30° C. and −80° C., and the mixture of reactants flowed into the chamber in operation 205 includes C₂Br₂F₄. In another embodiment, operation 203 involves cooling the substrate to a temperature between about −30° C. and −80° C., and the mixture of reactants flowed into the chamber in operation 205 includes CF₄. In another embodiment, operation 203 involves cooling the substrate to a temperature between about −50° C. and −30° C. (e.g., about −40° C.) and the mixture of reactants flowed into the chamber in operation 205 includes C₂BrF₅. Various alternative combinations of particular gases and temperatures may be used. In another embodiment, operation 203 involves cooling the substrate to a temperature between about −30° C. and −80° C., and the mixture of reactants flowed into the chamber in operation 205 includes CHF₃. In another embodiment, operation 203 involves cooling the substrate to a temperature between about −30° C. and −80° C., and the mixture of reactants flowed into the chamber in operation 205 includes C₂F₅I. In another embodiment, operation 203 involves cooling the substrate to a temperature between about −30° C. and −80° C., and the mixture of reactants flowed into the chamber in operation 205 includes C₃F₈. In yet another embodiment, operation 203 involves cooling the substrate to a temperature between about −30° C. and −80° C., and the mixture of reactants flowed into the chamber in operation 205 includes CS₂.

Cryogenic temperatures have been used for etching semiconductor substrates in certain instances. However, such efforts have been concentrated on etching silicon, rather than dielectric material. A highly selective silicon etch can be performed at below about −80° C. The etch is selective to the silicon in comparison with silicon dioxide material and carbon-based mask materials. Such conditions are not conducive to etching dielectric materials such as silicon oxide.

### Apparatus

The methods described herein may be performed by any suitable apparatus. A suitable apparatus includes hardware for accomplishing the process operations and a system controller having instructions for controlling process operations in accordance with the present embodiments. For example, in some embodiments, the hardware may include one or more process stations included in a process tool.

FIGS. 4A-4C illustrate an embodiment of an adjustable gap capacitively coupled confined RF plasma reactor 400 that may be used for performing the etching operations described herein. As depicted, a vacuum chamber 402 includes a chamber housing 404, surrounding an interior space housing a lower electrode 406. In an upper portion of the chamber 402 an upper electrode 408 is vertically spaced apart from the lower electrode 406. Planar surfaces of the upper and lower electrodes 408, 406 are substantially parallel and orthoganol to the vertical direction between the electrodes. Preferably the upper and lower electrodes 408, 406 are circular and coaxial with respect to a vertical axis. A lower surface of the upper electrode 408 faces an upper surface of the lower electrode 406. The spaced apart facing electrode surfaces define an adjustable gap 410 therebetween. During operation, the lower electrode 406 is supplied RF power by an RF power supply (match) 420. RF power is supplied to the lower electrode 406 though an RF supply conduit 422, an RF strap 424 and an RF power member 426. A grounding shield 436 may surround the RF power member 426 to provide a more uniform RF field to the lower electrode 406. As described in commonly-owned U.S. Pat. No. 7,732,728, the entire contents of which are herein incorporated by reference, a wafer is inserted through wafer port 482 and supported in the gap 410 on the lower electrode 406 for processing, a process gas is supplied to the gap 410 and excited into plasma state by the RF power. The upper electrode 408 can be powered or grounded.

In the embodiment shown in FIGS. 4A-4C, the lower electrode 406 is supported on a lower electrode support plate 416. An insulator ring 414 interposed between the lower electrode 406 and the lower electrode Support plate 416 insulates the lower electrode 406 from the support plate 416.

An RF bias housing 430 supports the lower electrode 406 on an RF bias housing bowl 432. The bowl 432 is connected through an opening in a chamber wall plate 418 to a conduit support plate 438 by an arm 434 of the RF bias housing 430. In a preferred embodiment, the RF bias housing bowl 432 and RF bias housing arm 434 are integrally formed as one component, however, the arm 434 and bowl 432 can also be two separate components bolted or joined together.

The RF bias housing arm 434 includes one or more hollow passages for passing RF power and facilities, such as gas coolant, liquid coolant, RF energy, cables for lift pin control, electrical monitoring and actuating signals from outside the vacuum chamber 402 to inside the vacuum chamber 402 at a space on the backside of the lower electrode 406. The RF supply conduit 422 is insulated from the RF bias housing arm 434, the RF bias housing arm 434 providing a return path for RF power to the RF power supply 420. A facilities conduit 440 provides a passageway for facility components. Further details of the facility components are described in U.S. Pat. Nos. 5,948,704 and 7,732,728 and are not shown here for simplicity of description. The gap 410 is preferably surrounded by a confinement ring assembly or shroud (not shown), details of which can be found in commonly owned published U.S. Pat. No. 7,740,736 herein incorporated by reference. The interior of the vacuum chamber 402 is maintained at a low pressure by connection to a vacuum pump through vacuum portal 480.

The conduit support plate 438 is attached to an actuation mechanism 442. Details of an actuation mechanism are described in commonly-owned U.S. Pat. No. 7,732,728 incorporated herein by above. The actuation mechanism 442, such as a servo mechanical motor, stepper motor or the like is attached to a vertical linear bearing 444, for example, by a screw gear 446 such as a ball screw and motor for rotating the ball screw. During operation to adjust the size of the gap 410, the actuation mechanism 442 travels along the vertical linear bearing 444. FIG. 4A illustrates the arrangement when the actuation mechanism 442 is at a high position on the linear bearing 444 resulting in a small gap 410a. FIG. 4B illustrates the arrangement when the actuation mechanism 442 is at a mid position on the linear bearing 444. As shown, the lower electrode 406, the RF bias housing 430, the conduit support plate 438, the RF power supply 420 have all moved lower with respect to the chamber housing 404 and the upper electrode 408, resulting in a medium size gap 410b.

FIG. 4C illustrates a large gap 410c when the actuation mechanism 442 is at a low position on the linear bearing. Preferably, the upper and lower electrodes 408, 406 remain co-axial during the gap adjustment and the facing surfaces of the upper and lower electrodes across the gap remain parallel.

This embodiment allows the gap 410 between the lower and upper electrodes 406, 408 in the CCP chamber 402 during multi-step process recipes (BARC, HARC, and STRIP etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 406, 408.

FIG. 4A illustrates laterally deflected bellows 450 sealed at a proximate end to the conduit support plate 438 and at a distal end to a stepped flange 428 of chamber wall plate 418. The inner diameter of the stepped flange defines an opening 412 in the chamber wall plate 418 through which the RF bias housing arm 434 passes. The distal end of the bellows 450 is clamped by a clamp ring 452.

The laterally deflected bellows 450 provides a vacuum seal while allowing vertical movement of the RF bias housing 430, conduit support plate 438 and actuation mechanism 442. The RF bias housing 430, conduit support plate 438 and actuation mechanism 442 can be referred to as a cantilever assembly. Preferably, the RF power supply 420 moves with the cantilever assembly and can be attached to the conduit support plate 438. FIG. 4B shows the bellows 450 in a neutral position when the cantilever assembly is at a mid position. FIG. 4C shows the bellows 450 laterally deflected when the cantilever assembly is at a low position.

A labyrinth seal 448 provides a particle barrier between the bellows 450 and the interior of the plasma processing chamber housing 404. A fixed shield 456 is immovably attached to the inside inner wall of the chamber housing 404 at the chamber wall plate 418 so as to provide a labyrinth groove 460 (slot) in which a movable shield plate 458 moves vertically to accommodate vertical movement of the cantilever assembly. The outer portion of the movable shield plate 458 remains in the slot at all vertical positions of the lower electrode 406.

In the embodiment shown, the labyrinth seal 448 includes a fixed shield 456 attached to an inner surface of the chamber wall plate 418 at a periphery of the opening 412 in the chamber wall plate 418 defining a labyrinth groove 460. The movable shield plate 458 is attached and extends radially from the RF bias housing arm 434 where the arm 434 passes through the opening 412 in the chamber wall plate 418. The movable shield plate 458 extends into the labyrinth groove 460 while spaced apart from the fixed shield 456 by a first gap and spaced apart from the interior surface of the chamber wall plate 418 by a second gap allowing the cantilevered assembly to move vertically. The labyrinth seal 448 blocks migration of particles spalled from the bellows 450 from entering the vacuum chamber interior 405 and blocks radicals from process gas plasma from migrating to the bellows 450 where the radicals can form deposits which are subsequently spalled.

FIG. 4A shows the movable shield plate 458 at a higher position in the labyrinth groove 460 above the RF bias housing arm 434 when the cantilevered assembly is in a high position (small gap 410a). FIG. 4C shows the movable shield plate 458 at a lower position in the labyrinth groove 460 above the RF bias housing arm 434 when the cantilevered assembly is in a low position (large gap 410c). FIG. 4B shows the movable shield plate 458 in a neutral or mid position within the labyrinth groove 460 when the cantilevered assembly is in a mid position (medium gap 410b). While the labyrinth seal 448 is shown as symmetrical about the RF bias housing arm 434, in other embodiments the labyrinth seal 448 may be asymmetrical about the RF bias arm 434.

FIG. 5 provides a simplified cross-sectional view of a portion of a substrate support 500. The substrate support 500 includes at least an upper plate 502 and a lower plate 504 separated by and in contact with a series of Peltier devices 508. The substrate (not shown) rests on the upper plate 502. Cooling channels 506 may be provided in the lower plate 504. The Peltier devices 508 operate to transfer heat from the upper plate 502 to the lower plate 504, where the heat is removed. In certain cases, the Peltier devices 508 may be used to transfer heat in the opposite direction, for example to actively heat the substrate. Additional details related to temperature controlled substrate supports are provided in U.S. patent application Ser. No. 13/908,676, incorporated by reference above. An alternate substrate support design (not shown) would consist of an upper plate 502 in contact with a lower plate 504, with cooling channels 506 in the lower plate to accommodate the circulation of refrigerant at cryogenic temperatures consistent with the claims herein. One example of a commercially available circulation unit is the Polycold Cryochiller model “MaxCool 2500” manufactured by Brooks Automation of Chelmsford, Mass. Heating the substrate, in order to avoid condensation or for other reasons discussed herein, may be accomplished by entering a mode that can elevate the support temperature over a time duration that would not prohibit its use based on excessive processing time.

### System Controller

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed. Certain references have been incorporated by reference herein. It is understood that any disclaimers or disavowals made in such references do not necessarily apply to the embodiments described herein. Similarly, any features described as necessary in such references may be omitted in the embodiments herein.

The subject matter of the present disclosure includes all novel and nonobvious combinations and sub-combinations of the various processes, systems and configurations, and other features, functions, acts, and/or properties disclosed herein, as well as any and all equivalents thereof.

1. A method of etching a feature in a substrate comprising dielectric material, the method comprising:
(a) receiving the substrate in a substrate holder in a chamber, the substrate holder comprising a chiller configured to cool the substrate;
(b) cooling the substrate by cooling the chiller to a temperature of about −20° C. or lower; and
(c) flowing a mixture of reactants into the chamber, generating a plasma from the mixture of reactants, and etching the dielectric material of the substrate to form the feature in the substrate, wherein the mixture of reactants comprises at least one reactant selected from the group consisting of: an iodine-containing fluoride, hydrogen iodide (HI), hydrogen bromide (HBr), iodine monobromide (IBr), sulfur dioxide (SO₂), carbon disulfide (CS₂), and carbonyl sulfide (COS).

2. The method of claim 1, wherein the mixture of reactants comprises the hydrogen iodide (HI).

3. The method of claim 1, wherein the mixture of reactants comprises the hydrogen bromide (HBr).

4. The method of claim 3, wherein the substrate is cooled by cooling the chiller to a temperature of about −60° C. or lower.

5. The method of claim 1, wherein the mixture of reactants comprises at least one reactant selected from the group consisting of: iodine monobromide (IBr) and hydrogen bromide (HBr).

6. The method of claim 1, wherein the mixture of reactants comprises the iodine monobromide (IBr).

7. The method of claim 1, wherein the mixture of reactants comprises the sulfur dioxide (SO₂).

8. The method of claim 7, wherein the substrate is cooled by cooling the chiller to a temperature of about −40° C. or lower.

9. The method of claim 1, wherein the mixture of reactants comprises the carbon disulfide (CS₂).

10. The method of claim 1, wherein the mixture of reactants comprises at least one reactant selected from the group consisting of sulfur dioxide (SO₂), carbon disulfide (CS₂), and carbonyl sulfide (COS).

11. The method of claim 10, wherein the mixture of reactants comprises the carbonyl sulfide (COS).

12. The method of claim 1, wherein the mixture of reactants comprises at least one iodine-containing fluoride selected from the group consisting of: iodine monofluoride (IF), iodine trifluoride (IF₃), iodine pentafluoride (IF₅), and iodine heptafluoride (IF₇).

13. The method of claim 12, wherein the mixture of reactants comprises at least one iodine-containing fluoride selected from the group consisting of: iodine monofluoride (IF), iodine trifluoride (IF₃), and iodine heptafluoride (IF₇).

14. The method of claim 1, wherein the substrate is etched at two or more different sets of reaction conditions, the different sets of reaction conditions being different with respect to the chiller temperature such that the substrate is etched at two or more different temperatures.

15. The method of claim 1, wherein the chiller reaches a temperature between about −100° C. and about −20° C. during etching.

16. The method of claim 1, wherein the dielectric material of the substrate comprises layers of silicon oxide, wherein the layers of silicon oxide alternate with layers of polysilicon.

17. The method of claim 1, wherein the dielectric material of the substrate comprises layers of silicon oxide and layers of silicon nitride, wherein the layers of silicon oxide alternate with the layers of silicon nitride.

18. The method of claim 1, wherein the feature is etched to a final aspect ratio of at least about 5:1.

19. The method of claim 1, wherein a protective film forms on sidewalls of the feature during etching, wherein the protective film prevents or slows lateral etching of the feature as the feature is etched in a vertical direction in the substrate.

20. An apparatus for etching a feature in a substrate comprising dielectric material, the apparatus comprising:
a reaction chamber;
a substrate support comprising a chiller configured to cool the substrate;
an inlet for introducing process gases to the reaction chamber;
an outlet for removing material from the reaction chamber;
a plasma source; and
a controller configured to cause:
(a) receiving the substrate in the substrate support;
(b) cooling the substrate by cooling the chiller to a temperature of about −20° C. or lower; and
(c) flowing a mixture of reactants into the reaction chamber, using the plasma source to generate a plasma from the mixture of reactants, and etching the dielectric material of the substrate to form the feature in the substrate, wherein the mixture of reactants comprises at least one reactant selected from the group consisting of: an iodine-containing fluoride, hydrogen iodide (HI), hydrogen bromide (HBr), iodine monobromide (IBr), sulfur dioxide (SO₂), carbon disulfide (CS₂), and carbonyl sulfide (COS).
